(19) United States
(12) Patent Application Publication
(10) Pub. No.: US 2007/0119702 A1
(43) Pub. Date: May 31, 2007

(54) Method for sputtering a multilayer film on a sheet workpiece at a low temperature

(76) Inventors: Jau-Jier Chu, Hsin-Chu (TW); Hsu-Fu Hung, Hsin-Chu (TW); I-Wen Lee, Hsin-Chu (TW); Chien-Min Weng, Hsin-Chu (TW); Tzu-Wen Chu, Hsin-Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/289,289

(22) Filed: Nov. 30, 2005

(51) Int. Cl. C23C 14/00

(52) U.S. Cl. 204/192.15

(57) ABSTRACT

A method for sputtering a multilayer film on a sheet workpiece at a low temperature of the present invention has the following steps: employing plasma to clean a surface of a sheet workpiece, sputtering at least one metal oxide or semiconductor oxide on the sheet workpiece, and sputtering at least one ITO transparent electric layer on the sheet workpiece. The film sputtering process of the sheet workpiece employs continuously connecting work stations, thereby controlling delay time between the work stations of the sheet workpiece within a given range. The sheet workpiece is made from a macromolecular material.

### BACKGROUND OF THE INVENTION

1 . Field of the Invention

The present invention relates to a method for sputtering a multilayer film on a sheet workpiece at a low temperature, and more particularly to a method based on the characteristic that sheet workpieces are ready to dispose in a continuous product line. Arranges continuous manufacturing process, employs plasma to clean surfaces of the workpieces, and combines with a conventional sputtering machine, thereby achieving convenience of installation and mass production of advanced material.

2 . Description of the Related Art

The ITO advanced multilayer film panel is very important in the supply of photoelectric raw and processed material. Along with the developing of photoelectric industry, it is also important to keep a low defects, controllable-manufacturing, costs-reducing and high-speed production method. The applications of manufacturing an ITO advanced multilayer film panel are related to many kinds of photoelectric products, such as an LCD, an OLED display, a field emission display, and touch panel. Although there are different applications of the ITO advanced multilayer film panel, the requirement of quality of each industry is the same. As to the manufacturing technology related to the ITO advanced multilayer film panel, it is well known that from the substrate of the photoelectric industry to the raw and processed material of a transparent electrode, almost all processes of the advanced panel are based on the ITO advanced multilayer film. The ITO advanced multilayer film panel and other electronic modules are assembled together in a linking structure, thereby forming an electronic product for achieving a given design function. The ITO advanced multilayer film panel must have three functions, power distribution, signal distribution, and transparency.

FIG. 1 is a schematic view of a reel-type manufacturing process of a conventional ITO multilayer film panel. A raw material roll 10a, a plasma 30a film sputtering process (ITO or oxide layer in general), and a material collection roll 20a are deposited in sequence. When the multilayer film sputtering process is done, a long product line is required. A material tensile force between the raw material roll 10a and the material collection roll 20a is insufficient. So a tensile wheel is added. However, the tensile wheel may deflect and lock the material strip. Thus, the conventional multilayer film sputtering method not only has a problem that equipment is not easy to configure, but also has a problem of maintenance. So the convenience in manufacture thereof is limited to a product sputtered with a few film layers. It is necessary to use a quick and reliable method to manufacture the ITO advanced multilayer film panel, particularly when manufacturing a basic material of the macromolecule type, such as transparent acryl (PMMA).

Therefore, it is important to manufacture the ITO advanced multilayer film panel and control the manufacturing process stably. This is particularly important for the photoelectric industry, which needs ITO advanced multilayer film panels.

### SUMMARY OF THE INVENTION

Accordingly, an object of the present invention is to provide a method for puttering a multilayer film on a sheet workpiece at a low temperature (may be applied in manufacturing raw material of a multilayer film) which facilitates stable manufacture and manufacture control, which can be easily combined with a conventional sputtering machine, and may be applied to optical products (such as an LCD, an OLED display, a field emission display, an optical sensor, or a touch panel) of which the raw and processed material is the ITO advanced multilayer film panel, and may provide a stable process with low cost and high quality.

To achieve the above-mentioned objects, the present invention provides a method for sputtering a multilayer film on a sheet workpiece at a low temperature, based on the characteristics that sheet workpieces are ready to dispose in a continuous product line, are arranged in a continuous manufacturing process, employs plasma to clean surfaces of the workpieces, cooperates with conventional manufacturing process and easily made peripheral equipment for combining steps of all processes together.

The method for sputtering a multilayer film on a sheet workpiece at a low temperature of the present invention includes the following steps: employing plasma to clean a surface of a sheet workpiece, sputtering at least one metal oxide or semiconductor oxide on the sheet workpiece, and sputtering at least one ITO transparent electric layer on the sheet workpiece. The film sputtering process of the sheet workpiece employs continuously connecting work stations, thereby controlling delay time between the work stations of the sheet workpiece within a given range. The sheet workpiece is made from a macromolecular material.

### BRIEF DESCRIPTION OF THE DRAWINGS

Other objects, advantages and novel features of the present invention will be drawn from the following detailed embodiments of the present invention with attached drawings, in which:

FIG. 1 is a schematic view showing a conventional film sputtering product line;

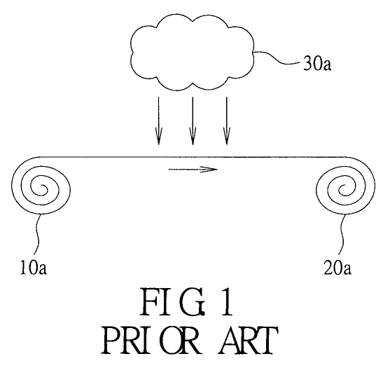

FIG. 2A is a schematic view showing a front portion of a product line of an ITO advanced multilayer film panel manufactured by the method of the present invention;

FIG. 2B is a schematic view showing a rear portion of a product line of an ITO advanced multilayer film panel manufactured by the method of the present invention;

FIG. 3A is a table showing manufacture data of a front portion of a product line of the ITO advanced multilayer film panel manufactured by the method of the present invention;

FIG. 3B is a table showing manufacture data of a rear portion of a product line of the ITO advanced multilayer film panel manufactured by the method of the present invention; and

FIG. 4 is a flow chart of the method of the present invention.

### DETAILED DESCRIPTION OF PREFERRED EMBODIMENTS

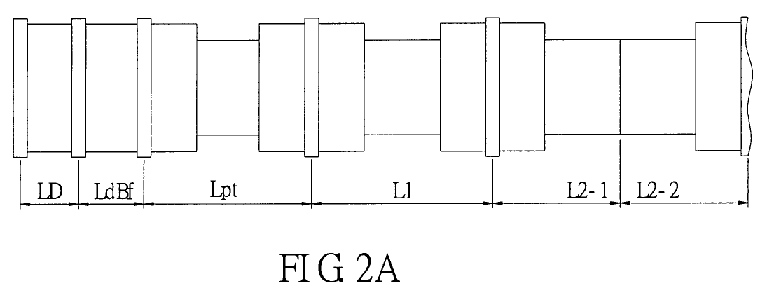

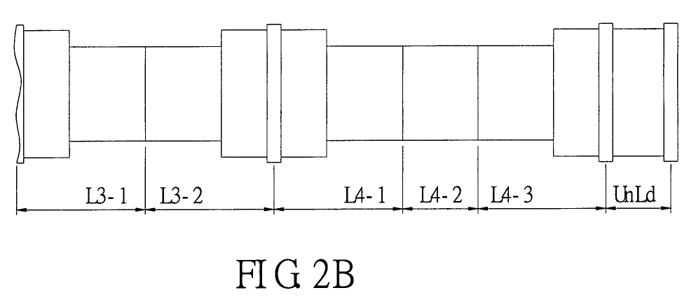

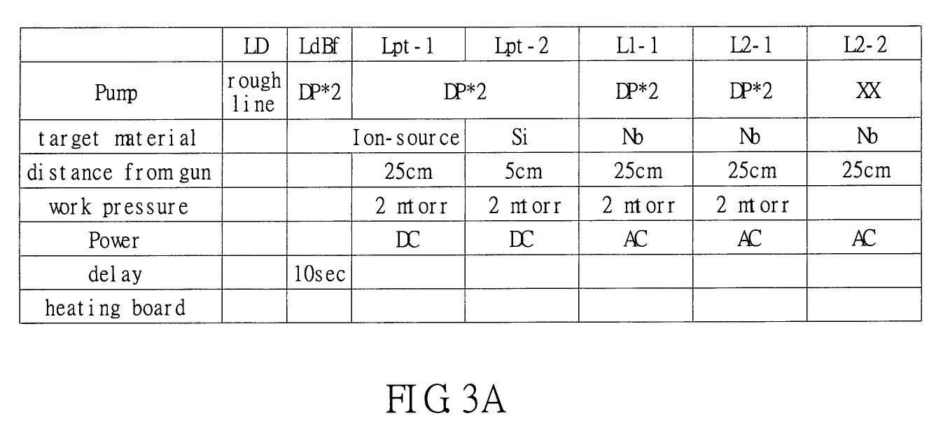

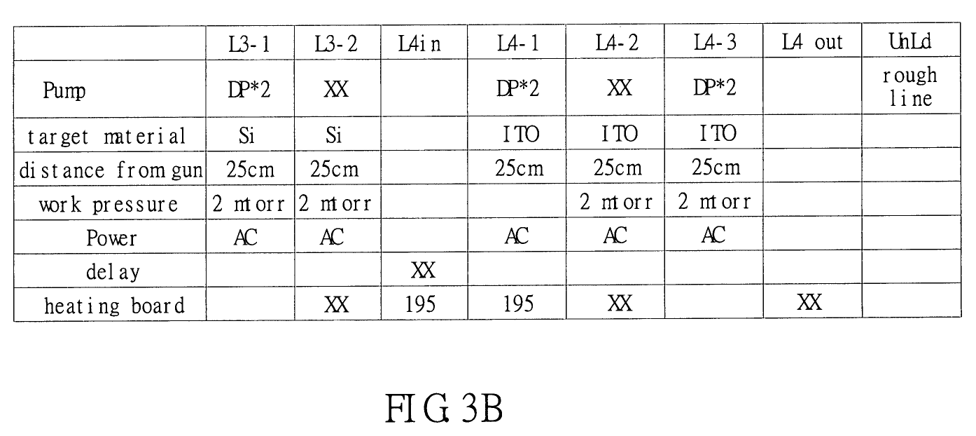

Referring to FIGS. 2A, 2B, 3A and 3B, an embodiment of the present invention is shown. The goal is to manufacture continuously sheet workpieces made from acryl board (PMMA). The continuous manufacturing process includes steps of cleaning a surface of a sheet workpiece with plasma (steps LdBf and Lpt-1), and cooperating with conventional manufacturing processes and easily made peripheral equipment for combining steps of all processes together (steps Lpt-2 and UnLd). As to a diagram of the relationship between the steps for the programming process of the ITO advanced multilayer film panel and specifications of the equipment, at the beginning, the acryl board enters a feed-in step (LD, LOAD), and then enters steps (Lpt-1 to L3-2) of sputtering at least one metal oxide or semiconductor oxide on the sheet workpiece. It can be observed from the drawings that in this embodiment the at least one silicon oxide (target materials are silicon, but an oxide film is formed during sputtering) and one niobium oxide (the target material is niobium but the oxide film is formed during sputtering) are sputtered. In a latter process, at least one ITO transparent electric layer (L4in to L4out) is sputtered. This embodiment shows that the sheet workpiece is very convenient to arrange in a product line of a conventional sputtering product. A product line of processing a semiconductor corresponding to a chip is slightly changed and can be used in the continuous sputtering process of the advanced multilayer film panel of the present invention. The theory or basis of the method of the present invention can be seen from the drawings of this embodiment.

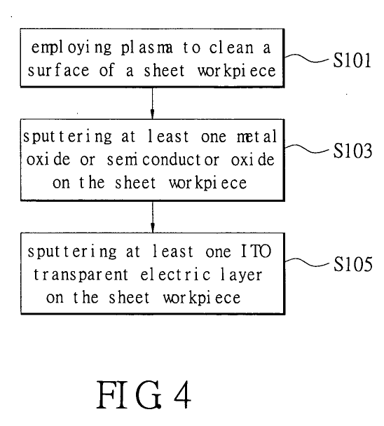

Referring to FIG. 4, a method for sputtering a multilayer film on a sheet workpiece at a low temperature of the present invention includes the following steps: employing plasma to clean a surface of a sheet workpiece (S101), sputtering at least one metal oxide or semiconductor oxide on the sheet workpiece (S103), and sputtering at least one ITO transparent electric layer on the sheet workpiece (S105). The film sputtering process of the sheet workpiece employs continuously connecting work stations, thereby controlling delay time between the work stations of the sheet workpiece within a given range. The sheet workpiece is made from a macromolecular material.

The details of the embodiment of the present invention may be varied as follows. The film sputtering process of the sheet workpiece is maintained within a given range of cleaning levels (sputtering requires a clean surface of the workpiece). The sheet workpiece is transferred between the film sputtering work stations by a conveyer belt or an automatic cart (similar to the semiconductor process). The metal oxide is niobium oxide or the semiconductor oxide is silicon oxide. Before all of the manufacture steps, a step of forming the sheet workpiece is further provided (integrating an upper process to control the size of the workpiece).

The present invention provides a method for sputtering a multilayer film on a sheet workpiece at a low temperature (may be applied in manufacturing raw material of a multilayer film). The method facilitates stable manufacture and manufactures control, and can be easily combined with a conventional sputtering machine. The method may be applied to optical products (such as an LCD, an OLED display, a field emission display, or an optical sensor) of which the raw and processed material are ITO advanced multilayer film panels. The method of the present invention may provide a stable process with low cost and high quality and may be used cheaply and with few changes to the conventional product line of photoelectric industry.

The method of the present invention has the following advantages: 1) a new process is easy to realize with a low cost of newly added equipment and conventional technology; 2) quick and continuous process; 3) it may be applied to other similar optical products and be compatible with the conventional process.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A method for sputtering a multilayer film on a sheet workpiece at a low temperature, comprising the following steps:
employing plasma to clean a surface of a sheet workpiece;
sputtering at least one metal oxide or semiconductor oxide on the sheet workpiece; and
sputtering at least one ITO transparent electric layer on the sheet workpiece;
wherein the film sputtering process of the sheet workpiece employs continuously connecting work stations, thereby controlling delay time between the work stations of the sheet workpiece within a given range, and the sheet workpiece is made from a macromolecular material.

2. The method as claimed in claim 1, wherein the film sputtering process of the sheet workpiece is maintained within a given range of cleaning levels.

3. The method as claimed in claim 1, wherein the sheet workpiece is transferred between the film sputtering work stations by a conveyer belt or an automatic cart.

4. The method as claimed in claim 1, wherein the metal oxide is niobium oxide or the semiconductor oxide is silicon oxide.

5. The method as claimed in claim 1, further comprising a step of forming the sheet workpiece before all of the manufacture steps.
